(19) United States
(12) Patent Application Publication
(10) Pub. No.: US 2026/0372013 A1
(43) Pub. Date: Nov. 19, 2026

(54) BONDING APPARATUS, BONDING SYSTEM, AND BONDING METHOD

(71) Applicant: Tokyo Electron Limited, Tokyo (JP)

(72) Inventor: Tetsuya MAKI, Koshi-shi, Kumamoto (JP)

(73) Assignee: Tokyo Electron Limited, Tokyo (JP)

(21) Appl. No.: 19/138,751

(22) PCT Filed: Dec. 4, 2023
(86) PCT No.: PCT/JP2023/043234

§ 371 Date: Jun. 13, 2025

(30) Foreign Application Priority Data
Dec. 15, 2022 (JP) 2022-200235

(51) Int. Cl. H10P 72/78; H10P 10/00; H10P 72/00

(52) U.S. Cl. CPC H10P 72/78; H10P 10/128; H10P 72/0402; H10P 72/0411; H10P 72/0428; H10P 72/0468; H10P 72/0606

(57) ABSTRACT

A bonding apparatus includes a first holder, a second holder and a striker. The first holder is configured to hold a first substrate from above. The second holder is disposed below the first holder, and configured to attract and hold a second substrate from below. The striker is configured to press a central portion of the first substrate into contact with the second substrate. The first holder includes a main body and a negative pressure formation section. The main body has a bottom surface facing the first substrate. The negative pressure formation section is configured to form a negative pressure in a space between the bottom surface of the main body and a top surface of the first substrate that are spaced apart from each other as a result of being pressed by the striker.

### TECHNICAL FIELD

The various aspects and embodiments described herein pertain generally to a bonding apparatus, a bonding system, and a bonding method.

### BACKGROUND

Conventionally, there is known a bonding apparatus that bonds substrates such as semiconductor wafers together (see, for example, Patent Document 1).

### PRIOR ART DOCUMENT

Patent Document 1: Japanese Patent Laid-open Publication No. 2018-147944

### DISCLOSURE OF THE INVENTION

### Problems To Be Solved By The Invention

Exemplary embodiments provide a technique capable of improving bonding accuracy between substrates.

### Means For Solving The Problems

In an exemplary embodiment, a bonding apparatus includes a first holder, a second holder and a striker. The first holder is configured to hold a first substrate from above. The second holder is disposed below the first holder, and configured to attract and hold a second substrate from below. The striker is configured to press a central portion of the first substrate into contact with the second substrate. The first holder includes a main body and a negative pressure formation section. The main body has a bottom surface facing the first substrate. The negative pressure formation section is configured to form a negative pressure in a space between the bottom surface of the main body and a top surface of the first substrate that are spaced apart from each other as a result of being pressed by the striker.

### EFFECT OF THE INVENTION

According to the exemplary embodiments, it is possible to improve the bonding accuracy between the substrates.

### BRIEF DESCRIPTION OF THE DRAWINGS

FIG. 1 is a schematic diagram illustrating a configuration of a bonding system according to an exemplary embodiment.

FIG. 2 is a schematic diagram illustrating the configuration of the bonding system according to the exemplary embodiment.

FIG. 3 is a schematic diagram illustrating a state of a first substrate and a second substrate before they are bonded to each other according to the exemplary embodiment.

FIG. 4 is a schematic diagram illustrating a configuration of a bonding apparatus according to the exemplary embodiment.

FIG. 5 is a schematic diagram illustrating the configuration of the bonding apparatus according to the exemplary embodiment.

FIG. 6 is a schematic diagram illustrating a first holder and a second holder according to the exemplary embodiment.

FIG. 7 is a schematic diagram that provides an example of expansion of a bonding region.

FIG. 8 is a schematic diagram that provides an example of the expansion of the bonding region.

FIG. 9 is a schematic diagram illustrating the first holder seen from below.

FIG. 10 is a schematic perspective view that provides an enlarged view of a bottom side of a main body.

FIG. 11 is a schematic diagram illustrating the first holder seen from below.

FIG. 12 is a flowchart showing some of the processes performed by the bonding system according to the exemplary embodiment.

FIG. 13 is an explanatory diagram illustrating an operation in a bonding processing.

FIG. 14 is an explanatory diagram illustrating an operation in the bonding processing.

FIG. 15 is a schematic diagram that provides an example of expansion of a bonding region in the bonding apparatus according to the exemplary embodiment.

### DETAILED DESCRIPTION

Hereinafter, embodiments for a bonding apparatus, a bonding system, and a bonding method according to the present disclosure (hereinafter, referred to as “exemplary embodiments”) will be described in detail with reference to the accompanying drawings. Further, it should be noted that the present disclosure is not limited by the exemplary embodiments.

In the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “θ direction.”

### Bonding System

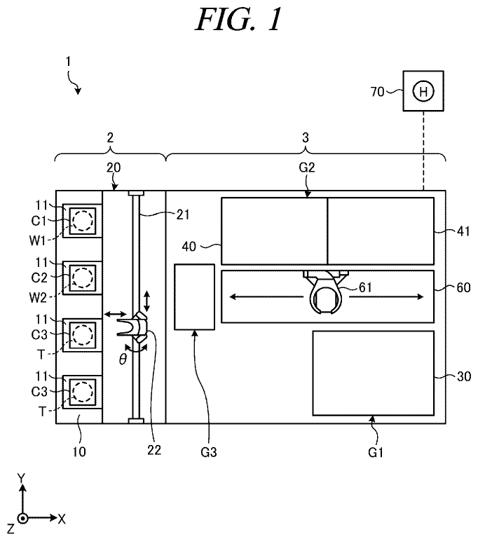

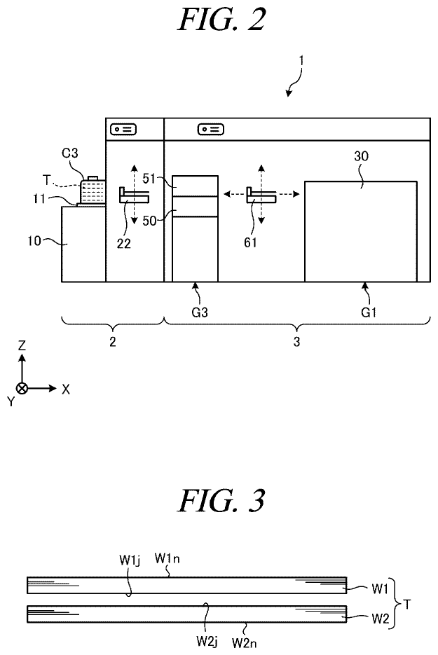

First, a configuration of a bonding system according to an exemplary embodiment will be described with reference to FIG. 1 to FIG. 3. FIG. 1 and FIG. 2 are schematic diagrams illustrating the configuration of the bonding system according to the exemplary embodiment. FIG. 3 is a schematic diagram illustrating a first substrate and a second substrate before being bonded to each other according to the exemplary embodiment.

A bonding system 1 shown in FIG. 1 forms a combined substrate T by bonding a first substrate W1 and a second substrate W2 (see FIG. 3).

The first substrate W1 is a substrate on which multiple electronic circuits are formed on a semiconductor substrate such as a silicon wafer or a compound semiconductor wafer. The second substrate W2 is a bare wafer on which no electronic circuit is formed. The first substrate W1 and the second substrate W2 have substantially the same diameter. Further, the second substrate W2 may be a substrate on which multiple electronic circuits are formed on a semiconductor substrate such as a silicon wafer or a compound semiconductor wafer, like the first substrate W1.

In the following, as shown in FIG. 3, among plate surfaces of the first substrate W1, the plate surface to be bonded to the second substrate W2 will be referred to as “bonding surface W1j,” and the plate surface opposite the bonding surface W1j will be referred to as “non-bonding surface W1n.” Likewise, among plate surfaces of the second substrate W2, the plate surface to be bonded to the first substrate W1 will be referred to as “bonding surface W2j,” and the plate surface opposite the bonding surface W2j will be referred to as “non-bonding surface W2n.”

As shown in FIG. 1, the bonding system 1 is equipped with a carry-in/out station 2 and a processing station 3. The carry-in/out station 2 is located on the negative X-axis side of the processing station 3, and is connected as a single structure with the processing station 3.

The carry-in/out station 2 includes a placement table 10 and a transfer section 20. The placement table 10 is equipped with a multiple number of placement plates 11. Provided on the placement plates 11 are cassettes C1, C2 and C3 each of which accommodates therein a plurality of (e.g., 25 sheets of) substrates horizontally. For example, the cassette C1 is for accommodating first substrates W1; the cassette C2, second substrates W2; and the cassette C3, combined substrates T.

The transfer section 20 is provided adjacent to the positive X-axis side of the placement table 10. This transfer section 20 is provided with a transfer path 21 extending in the Y-axis direction and a transfer device 22 configured to be movable along this transfer path 21. The transfer device 22 is configured to be movable in the X-axis direction as well as in the Y-axis direction and pivotable around the Z-axis. The transfer device 22 serves to transfer the first substrates W1, the second substrates W2, and the combined substrates T between the cassettes C1 to C3 placed on the placement plates 11 and a third processing block G3 of the processing station 3 to be described later.

Further, the number of the cassettes C1 to C3 disposed on the placement plates 11 is not limited to the shown example. Moreover, in addition to the cassettes C1, C2, and C3, a cassette for collecting a defective substrate may be also disposed on the placement plate 11.

The processing station 3 is provided with, for example, three processing blocks G1, G2, and G3. The first processing block G1 is located on the front side (negative Y-axis side of FIG. 1) of the processing station 3. The second processing block G2 is located on the rear side (positive Y-axis side of FIG. 1) of the processing station 3, and the third processing block G3 is located on the carry-in/out station 2 side (negative X-axis side of FIG. 1) of the processing station 3.

The first processing block G1 is equipped with a surface modifying apparatus 30 configured to modify the bonding surface W1j of the first substrate W1 and the bonding surface W2j of the second substrate W2. The surfacy modifying apparatus 30 cuts a SiO₂ bond in the bonding surfaces W1j and W2j of the first and second substrates W1 and W2 to form a single bond of SiO, thus modifying the bonding surfaces W1j and W2j so that they can be easily hydrophilized afterwards.

To elaborate, in the surface modifying apparatus 30, an oxygen gas or a nitrogen gas as a processing gas is excited into plasma in, for example, a decompressed atmosphere to be ionized. Then, the oxygen ions or the nitrogen ions are radiated to the bonding surfaces W1j and W2j of the first and second substrates W1 and W2, so that the bonding surfaces W1j and W2j are plasma-processed to be modified.

In the second processing block G2, a surface hydrophilizing apparatus 40 and a bonding apparatus 41 are arranged. The surface hydrophilizing apparatus 40 is configured to hydrophilize the bonding surfaces W1j and W2j of the first and second substrates W1 and W2 with, for example, pure water, and also serves to clean the bonding surfaces W1j and W2j. Specifically, the surface hydrophilizing apparatus 40 supplies the pure water onto the first substrate W1 or the second substrate W2 held by, for example, a spin chuck, while rotating the first substrate W1 or the second substrate W2. As a result, the pure water supplied onto the first substrate W1 or the second substrate W2 is diffused on the bonding surface W1j or W2j of the first or second substrate W1 or W2, so that the bonding surfaces W1j and W2j are hydrophilized.

The bonding apparatus 41 is configured to bond the hydrophilized first and second substrates W1 and W2 by an intermolecular force. Details of this bonding apparatus 41 will be described later.

In the third processing block G3, transition (TRS) devices 50 and 51 for the first substrate W1, the second substrate W2, and the combined substrate T are provided in this order from the bottom, as illustrated in FIG. 2.

A transfer section 60 is formed in an area surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example. This transfer device 61 moves within the transfer section 60 to transfer the first substrate W1, the second substrate W2, and the combined substrate T to preset apparatuses within the first processing block G1, the second processing block G2, and the third processing block G3 adjacent to the transfer section 60.

Also, the bonding system 1 is equipped with a control device 70. The control device 70 is configured to control an operation of the bonding system 1. This control device 70 is, for example, a computer, and has a controller and a storage both of which are not illustrated. The controller includes a microcomputer having a central processing unit (CPU), a read only memory (ROM), a random access memory (RAM), input/output ports, etc., and various types of circuits. The CPU of such a microcomputer reads and executes a program stored in the ROM, thus implementing a control to be described later. Further, the storage is implemented by, by way of non-limiting example, a semiconductor memory element such as a RAM or a flash memory, or a storage device such as a hard disk or an optical disk.

In addition, such a program may have been recorded on a computer-readable recording medium, and may be installed from the recording medium into the storage of the control device 70. The computer-readable recording medium may be, by way of non-limiting example, a hard disk (HD), a flexible disk (FD), a compact disk (CD), a magnet optical disk (MO), a memory card, or the like.

### Bonding Apparatus

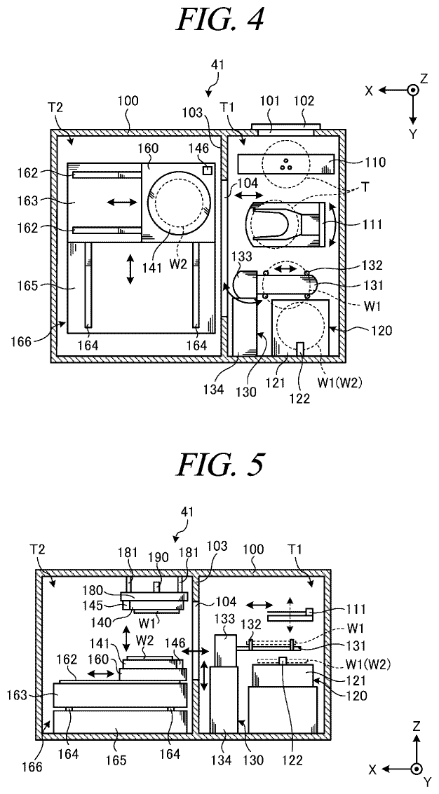

Now, a configuration of the bonding apparatus 41 will be explained with reference to FIG. 4 and FIG. 5. FIG. 4 and FIG. 5 are schematic diagrams illustrating the configuration of the bonding apparatus 41 according to the exemplary embodiment.

As depicted in FIG. 4, the bonding apparatus 41 includes a processing vessel 100 having a hermetically sealable inside. A carry-in/out opening 101 for the first substrate W1, the second substrate W2, and the combined substrate T is formed at a side surface of the processing vessel 100 on the side of the transfer section 60, and an opening/closing shutter 102 is provided at this carry-in/out opening 101.

The inside of the processing vessel 100 is partitioned into a transfer section T1 and a processing section T2 by an inner wall 103. The aforementioned carry-in/out opening 101 is formed at the side surface of the processing vessel 100 in the transfer section T1. Further, the inner wall 103 is also provided with a carry-in/out opening 104 for the first substrate W1, the second substrate W2, and the combined substrate T.

In the transfer section T1, a transition device 110, a substrate transfer mechanism 111, an inverting mechanism 130, and a position adjusting mechanism 120 are arranged in this order from the carry-in/out opening 101 side, for example.

The transition device 110 temporarily places therein the first substrate W1, the second substrate W2, and the combined substrate T. The transition device 110 is formed in, for example, two levels, and is thus capable of placing therein any two of the first substrate W1, the second substrate W2, and the combined substrate T at the same time.

As shown in FIG. 4 and FIG. 5, the substrate transfer mechanism 111 has a transfer arm configured to be movable in a vertical direction (Z-axis direction) and horizontal directions (X-axis direction and Y-axis direction) and pivotable around a vertical axis (θ direction), for example. The substrate transfer mechanism 111 is capable of transferring the first substrate W1, the second substrate W2, and the combined substrate T in the transfer section T1 or between the transfer section T1 and the processing section T2.

The position adjusting mechanism 120 is configured to adjust directions of the first substrate W1 and the second substrate W2 in the horizontal direction. Specifically, the position adjusting mechanism 120 includes a base 121 equipped with a non-illustrated holder configured to hold and rotate the first and second substrates W1 and W2, and a detector 122 configured to detect the positions of notches of the first and second substrates W1 and W2. By detecting the positions of the notches of the first and second substrates W1 and W2 with the detector 122 while rotating the first substrate W1 and the second substrate W2 held by the base 121, the position adjusting mechanism 120 adjusts the positions of the notches. As a result, the directions of the first substrate W1 and the second substrate W2 are adjusted in the horizontal direction.

The inverting mechanism 130 is configured to invert front and rear surfaces of the first substrate W1. Specifically, the inverting mechanism 130 has a holding arm 131 configured to hold the first substrate W1. The holding arm 131 extends in a horizontal direction (X-axis direction). Further, the holding arm 131 is provided with holding members 132 configured to hold the first substrate W1 at, for example, four positions thereon.

The holding arm 131 is supported by a driver 133 that is equipped with, for example, a motor. The holding arm 131 is rotatable around a horizontal axis by this driver 133. Further, the holding arm 131 is also rotatable about the driver 133 and movable in a horizontal direction (X-axis direction). Below the driver 133, another driver (not shown) equipped with, for example, a motor is disposed. The driver 133 can be moved in a vertical direction by this another driver along a supporting column 134 that extends in the vertical direction.

In this way, the first substrate W1 held by the holding members 132 can be rotated around the horizontal axis by the driver 133, and can also be moved in the vertical and horizontal directions. Further, the first substrate W1 held by the holding members 132 can be moved between the position adjusting mechanism 120 and a first holder 140 to be described later by being rotated about the driver 133.

Provided in the processing section T2 are the first holder 140 configured to attract and hold a top surface (non-bonding surface W1n) of the first substrate W1 from above and a second holder 141 configured to attract and hold a bottom surface (non-bonding surface W2n) of the second substrate W2 from below. The second holder 141 is disposed below the first holder 140, and is configured to face the first holder 140. The first holder 140 and the second holder 141 are, for example, vacuum chucks.

As depicted in FIG. 5, the first holder 140 is supported by a supporting member 180 that is provided above the first holder 140. The supporting member 180 is fixed to a ceiling surface of the processing vessel 100 with, for example, a plurality of supporting columns 181 therebetween.

An upper imaging device 145 configured to image a top surface (bonding surface W2j) of the second substrate W2 held by the second holder 141 is provided at a lateral side of the first holder 140. The upper imaging device 145 may be, for example, a CCD camera.

The second holder 141 is supported by a first mover 160 that is disposed below the second holder 141. The first mover 160 serves to move the second holder 141 in a horizontal direction (X-axis direction) as will be described later. Also, the first mover 160 is configured to be able to move the second holder 141 in a vertical direction and to rotate it around a vertical axis.

The first mover 160 is provided with a lower imaging device 146 configured to image a bottom surface (bonding surface W1j) of the first substrate W1 held by the first holder 140. The lower imaging device 146 may be, for example, a CCD camera.

The first mover 160 is mounted to a pair of rails 162. The rails 162 are disposed at a bottom side of the first mover 160, and is elongated in a horizontal direction (X-axis direction). The first mover 160 is configured to be movable along the rails 162.

The pair of rails 162 are mounted to a second mover 163. The second mover 163 is mounted to a pair of rails 164. The rails 164 are provided on a bottom side of the second mover 163, and is elongated in a horizontal direction (Y-axis direction). The second mover 163 is configured to be movable in the horizontal direction (Y-axis direction) along the rails 164. Further, the pair of rails 164 are arranged on a placement table 165 which is provided on a bottom surface of the processing vessel 100.

The first mover 160, the second mover 163, etc., constitute a position aligning device 166. The position aligning device 166 moves the second holder 141 in the X-axis direction, the Y-axis direction, and the θ direction, thus allowing the first substrate W1 held by the first holder 140 and the second substrate W2 held by the second holder 141 to be aligned in the horizontal directions. Also, the position aligning device 166 moves the second holder 141 in the Z-axis direction as well, thus allowing the first substrate W1 held by the first holder 140 and the second substrate W2 held by the second holder 141 to be aligned in the vertical direction.

Here, although the second holder 141 is moved in the X-axis direction, the Y-axis direction, and the θ direction, the position aligning device 166 may be configured to move the second holder 141 in the X-axis direction and the Y-axis direction and move the first holder 140 in the θ direction, for example. Further, in the present exemplary embodiment, although it is the second holder 141 that is moved in the Z-axis direction, the position aligning device 166 may be configured to move, for example, the first holder 140 in the Z-axis direction.

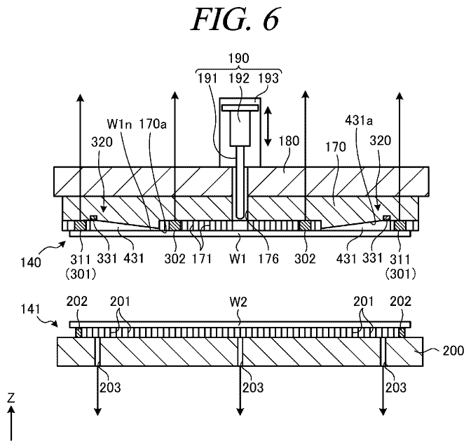

Now, the configuration of the first holder 140 and the second holder 141 will be described with reference to FIG. 6. FIG. 6 is a schematic diagram illustrating the first holder 140 and the second holder 141 according to the exemplary embodiment.

As shown in FIG. 6, the first holder 140 has a main body 170. The main body 170 is supported by the supporting member 180. The main body 170 has a diameter equal to or larger than that of the first substrate W1. Also, the main body 170 has a bottom surface 170a facing the first substrate W1. More specifically, the main body 170 has the bottom surface 170a facing the top surface (non-bonding surface W1n) of the first substrate W1 attracted to and held by the first holder 140. In the following, the non-bonding surface W1n of the first substrate W1 will sometimes be referred to as “top surface W1n” of the first substrate W1.

A through hole 176 is vertically formed through the supporting member 180 and the main body 170. The position of the through hole 176 corresponds to the center of the first substrate W1 that is attracted to and held by the first holder 140. A pressing pin 191 of a striker 190 is inserted through the through hole 176.

The striker 190 is disposed on a top surface of the supporting member 180, and is equipped with the pressing pin 191, an actuator 192, and a linearly moving mechanism 193. The pressing pin 191 is a cylindrical member extending in the vertical direction, and is supported by the actuator 192.

The actuator 192 is configured to generate a constant pressure in a certain direction (here, a vertically downward direction) by air supplied from, for example, an electro-pneumatic regulator (not shown). By the air supplied from the electro-pneumatic regulator, the actuator 192 can come into contact with a central portion of the first substrate W1 and is capable of controlling a pressing load applied to the central portion of the first substrate W1. A leading end of the actuator 192 is vertically movable through the through hole 176 by the air from the electro-pneumatic regulator.

The actuator 192 is supported by the linearly moving mechanism 193. The linearly moving mechanism 193 is configured to move the actuator 192 in the vertical direction by, for example, a driver having a motor embedded therein.

The striker 190 is configured as described above, and controls the movement of the actuator 192 by the linearly moving mechanism 193 and controls the pressing load on the first substrate W1 from the pressing pin 191 by the actuator 192. With this configuration, the striker 190 presses the central portion of the first substrate W1 held by the first holder 140 into contact with the second substrate W2.

The bottom surface 170a of the main body 170 is provided with multiple pins 171 that come into contact with the top surface (non-bonding surface W1n) of the first substrate W1. The multiple pins 171 have a diameter of, e.g., 0.1 mm to 1 mm and a height of, e.g., several tens of μm to several hundreds of μm. The multiple pins 171 are evenly arranged at an interval of, e.g., 2 mm.

In some of the area where the multiple pins 171 are provided, the first holder 140 has a plurality of outer attraction sections 301 and an inner attraction section 302 for attracting the first substrate W1, and a negative pressure formation section 320 to be described later. In the present exemplary embodiment, the plurality of outer attraction sections 301 and the negative pressure formation section 320 are arranged according to the anisotropy of the physical properties of the first substrate W1.

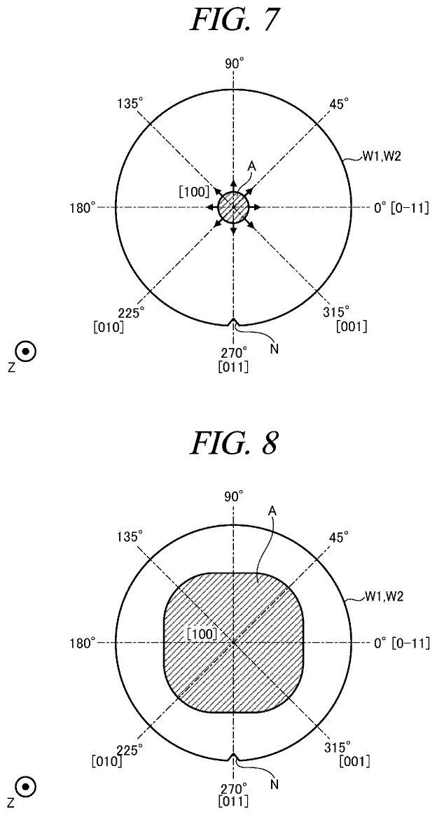

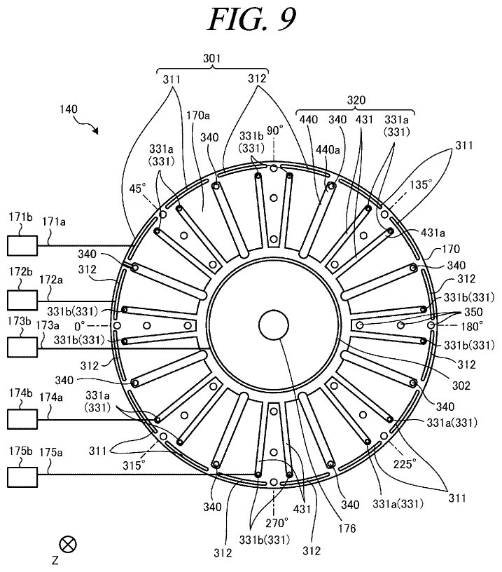

Here, the outer attraction sections 301, the inner attraction section 302, and the negative pressure formation section 320 belonging to the first holder 140 will be explained with reference to FIG. 7 to FIG. 9. FIG. 7 and FIG. 8 are schematic diagrams each providing an example of expansion of a bonding region. FIG. 9 is a schematic diagram of the first holder 140 seen from below. In addition, although a negative Miller index is generally represented by placing a bar over a corresponding numeral, it is represented in the present specification by placing a negative sign in front of the numeral.

As shown in FIG. 7, the first substrate W1 and the second substrate W2 are single-crystal silicon wafers with a [100] crystal orientation in the direction perpendicular to their front surfaces (bonding surfaces). Notches N are formed at outer edges of the first substrate W1 and the second substrate W2 corresponding to the [011] crystal orientation of the first substrate W1 and the second substrate W2. Also, the diameter of the first substrate W1 and the second substrate W2 is, for example, 300 mm.

When the central portion of the first substrate W1 is pressed down into contact with a central portion of the second substrate W2, the central portion of the first substrate W1 and the central portion of the second substrate W2 are bonded by an intermolecular force, forming a bonding region A at the central portions of both substrates. Thereafter, a bonding wave is generated, whereby the bonding region A expands from the central portions of the substrates toward the outer peripheries thereof, so that the entire bonding surfaces W1j and W2j of the first and second substrates W1 and W2 are bonded to each other.

In the case where the aforementioned bonding processing is performed by holding the first substrate W1 with a holder that is configured to hold the entire outer circumference of the first substrate W1, the bonding region A gets expanded in a non-uniform manner, not concentrically.

Specifically, as shown in FIG. 8, the bonding region A expands faster in a 45-degree direction than in a 90-degree direction. The 90-degree direction refers to a direction with a periodicity of 90 degrees (the directions of 0, 90, 180, and 270 degrees shown in FIG. 8) based on a direction extending from the center of the first substrate W1 toward the [0-11] crystal orientation, which is parallel to the front surface of the first substrate W1. The 45-degree direction refers to a direction with a periodicity of 90 degrees (the directions of 45, 135, 225, and 315 degrees shown in FIG. 8) based on a direction extending from the center of the first substrate W1 toward the [010] crystal orientation, which is parallel to the front surface of the first substrate W1. As a result, the shape of the bonding region A, which is initially circular, approaches a rectangle with vertices in the 45-degree directions when it expands. Thus, the bonding speed of the substrates becomes higher in the regions of the 45-degree directions, whereas the bonding speed of the substrates becomes lower in the regions of the 90-degree directions.

This is deemed to be due to the anisotropy of the physical properties, such as Young's modulus, of the first substrate W1 and the second substrate W2.

By way of example, values of the Young's modulus, Poisson's ratio, and shear modulus of the single-crystal silicon wafer vary with the periodicity of 90 degrees. Specifically, the Young's modulus of the single-crystal silicon wafer is highest in the 90-degree direction and lowest in the 45-degree direction. The Poisson's ratio and the shear modulus are highest in the 45-degree direction and lowest in the 90-degree direction.

As stated above, since the single-crystal silicon wafer has anisotropy in its physical properties such as Young's modulus, the distribution of stress and strain applied to the first substrate W1 is not concentric but uneven. This uneven distribution causes the bonding region A to become unevenly expanded, which may increase deformation (distortion) of the combined substrate T, raising a concern that the bonding accuracy between the substrates would be degraded.

Therefore, in the present exemplary embodiment, the negative pressure formation section 320 is provided to form a negative pressure in a space between the bottom surface 170a of the main body 170 and the top surface W1n of the first substrate W1, thereby appropriately suppressing the bonding speed between the substrates and improving the bonding accuracy between the substrates.

In addition, in the present exemplary embodiment, instead of holding the entire circumference of the outer periphery of the first substrate W1, the regions of the outer periphery of the first substrate W1 in the 45-degree directions, where the bonding region A expands fastest, are held by using the first holder 140, thereby improving the bonding accuracy between the substrates.

First, the outer attraction section 301 and the inner attraction section 302 will be explained. As illustrated in FIG. 9, the outer attraction section 301 and the inner attraction section 302 configured to attract the first substrate W1 by evacuation are provided at the bottom surface 170a of the main body 170 in the first holder 140. There are the plurality of (e.g., sixteen) outer attraction sections 301 and one inner attraction section 302. The outer attraction sections 301 and the inner attraction section 302 have the same height as the pins 171.

Each of the plurality of outer attraction sections 301 has an arc-shaped attraction region in a plan view. The plurality of outer attraction sections 301 are arranged at an outer periphery of the main body 170 along the circumferential direction thereof. Specifically, the plurality of outer attraction sections 301 include pairs of first outer attraction sections 311 arranged at an interval of 90 degrees, and pairs of second outer attraction sections 312 arranged shifted by 45 degrees from the pairs of first outer attraction sections 311 in the circumferential direction. That is, the plurality of outer attraction sections 301 include four pairs of first outer attraction sections 311 and four pairs of second outer attraction sections 312.

The four pairs of first outer attraction sections 311 and the four pairs of second outer attraction sections 312 attract and hold the outer periphery of the first substrate W1. The outer periphery of the first substrate W1 means a portion within 15% of the radius of the first substrate W1 from the outer edge of the first substrate W1.

The four pairs of first outer attraction sections 311 are arranged in the 45-degree direction on the first substrate W1. Specifically, the four pairs of first outer attraction sections 311 are arranged at positions where the center between the adjacent arc-shaped attraction regions coincides with the 45-degree direction on the first substrate W1. Also, the four pairs of second outer attraction sections 312 are arranged in the 90-degree direction on the first substrate W1 . . . Specifically, the four pairs of second outer attraction sections 312 are arranged at positions where the center between the adjacent arc-shaped attraction regions coincides with the 90-degree direction on the first substrate W1.

The four pairs of first outer attraction sections 311 are connected to one first vacuum pump 171b via a first suction line 171a, and attracts the first substrate W1 through evacuation by the first vacuum pump 171b. The four pairs of second outer attraction sections 312 are connected to one second vacuum pump 172b via a second suction line 172a, and attracts the first substrate W1 through evacuation by the vacuum pump 172b. Here, for ease of understanding, only the piping configuration of one of the plurality of first outer attraction sections 311 is shown. The same applies to the plurality of second outer attraction sections 312.

In this way, when the direction from the center of the first substrate W1 toward the [0-11] crystal orientation parallel to the front surface of the first substrate W1 is defined as 0 degree, the four pairs of first outer attraction sections 311 are arranged at an interval of 90 degrees with respect to the 45-degree direction. Also, the four pairs of second outer attraction sections 312 are arranged at an interval of 90 degrees with respect to the direction of 0 degree.

The inner attraction section 302 has a circular attraction region in a plan view. The inner attraction section 302 is disposed inward with respect to the outer attraction sections 301 in the radial direction of the main body 170. Also, the inner attraction section 302 is disposed outward with respect to the through hole 176, where the pressing pin 191 (see FIG. 6) of the striker 190 is inserted, in the radial direction of the main body 170. The inner attraction section 302 is connected to one third vacuum pump 173b via a third suction line 173a, and attracts the first substrate W1 through evacuation by the third vacuum pump 173b. Here, although the present exemplary embodiment has been described for the example where only one inner attraction section 302 is provided, the exemplary embodiment is not limited thereto, and multiple inner attraction sections may be provided.

Now, the negative pressure formation section 320 will be explained with reference to FIG. 6 and FIG. 9. As illustrated in FIG. 6 and FIG. 9, the negative pressure formation section 320 includes a suction opening 331, a suction-side groove portion 431, a supply opening 340 (see FIG. 9), and a supply-side groove portion 440 (see FIG. 9).

The suction opening 331 is plural in number (e.g., sixteen), and these suction openings 331 are arranged in the bottom surface 170a of the main body 170. The suction openings 331 are arranged along the circumferential direction at positions radially inward with respect to the outer attraction sections 301, near the outer periphery of the main body 170. Specifically, the plurality of suction openings 331 include pairs of first suction openings 331a arranged at an interval of 90 degrees, and pairs of second suction openings 331b arranged shifted by 45 degrees from the pairs of first suction openings 331a in the circumferential direction. That is, the plurality of suction openings 331 include four pairs of first suction openings 331a and four pairs of second suction openings 331b.

The four pairs of first suction openings 331a and the four pairs of second suction openings 331b are openings that suck in a gas (for example, air or a gas). In the present exemplary embodiment, a negative pressure is formed in the space between the bottom surface 170a of the main body 170 and the top surface W1nof the first substrate W1 by the sucking of the gas, which will be elaborated later.

The four pairs of first suction openings 331a are arranged in the 45-degree direction on the first substrate W1. Specifically, the four pairs of first suction openings 331a are arranged at positions where the center between the adjacent first suction openings 331a coincides with the 45-degree direction on the first substrate W1. Also, the four pairs of second suction openings 331b are arranged in the 90-degree direction on the first substrate W1. Specifically, the four pairs of second suction openings 331b are arranged at positions where the center between the adjacent second suction openings 331b coincides with the 90-degree direction on the first substrate W1.

The four pairs of first suction openings 331a are connected to one first suction pump 174b via a suction line 174a, and the gas near the first suction openings 331a is sucked in by the operation of the first suction pump 174b. The four pairs of second suction openings 331b are connected to one second suction pump 175b via a suction line 175a, and the gas near the second suction openings 331b is sucked in by the operation of the second suction pump 175b. Here, for ease of understanding, only the piping configuration of one of the plurality of first suction openings 331a is shown. The same applies to the plurality of second suction openings 331b.

The number and the layout of the first to third vacuum pumps 171b to 173b and the first and second suction pumps 174b and 175b described above are not particularly limited. The first to third vacuum pumps 171b to 173b and the first and second suction pumps 174b and 175b need to be provided for each area where an attraction pressure and a suction force are controlled independently.

The suction-side groove portion 431 is provided with the suction opening 331 (the first suction opening 331a or the second suction opening 331b). Therefore, the suction-side groove portion 431 is also plural in number (e.g., sixteen), the same as the suction openings 331. Specifically, the suction-side groove portions 431 are formed on the bottom surface 170a of the main body 170. The suction-side groove portions 431 are formed at positions radially inward with respect to the outer attraction sections 301 and radially outward with respect to the inner attraction section 302. The suction-side groove portion 431 is a long groove in a plan view, and is formed so that its lengthwise direction extends in the radial direction on the bottom surface 170a of the main body 170. In other words, the suction-side groove portion 431 is formed radially from the center of the bottom surface 170a of the main body 170 toward the outer periphery thereof.

The suction opening 331 is provided at a recessed portion (top surface in FIG. 6) 431a, which is an outer portion of the suction-side groove portion 431 in the radial direction, as shown in FIG. 6. In this way, since the suction opening 331 is formed at the suction-side groove portion 431, it is not in direct contact with the first substrate W1. Also, the suction-side groove portion 431 is formed so that the recessed portion (top surface in FIG. 6) 431a is tapered. Specifically, the suction-side groove portion 431 is formed so that its depth decreases as it goes from a radially outer side toward a radially inner side.

In addition, an end of the suction-side groove portion 431 on the radially inner side is set to be of a height lower than that of the pin 171, so it is not in direct contact with the first substrate W1 and is in an open state. Therefore, the suction opening 331 does not attract and hold the first substrate W1 by suction, but the exemplary embodiment is not limited thereto and the suction opening 331 may be configured to attract and hold the first substrate W1.

The arrangement position of the suction-side groove portion 431 will be described in detail. As shown in FIG. 9, the suction-side groove portion 431 in which the first suction opening 331a is provided is located in the 45-degree direction on the first substrate W1. Specifically, the suction-side groove portion 431 provided with the first suction opening 331a is disposed at a position where the center between the adjacent suction-side groove portions 431 respectively provided with the first suction opening 331a coincides with the 45-degree direction on the first substrate W1. Also, the suction-side groove portion 431 provided with the second suction opening 331b is located in the 90-degree direction on the first substrate W1. Specifically, the suction-side groove portion 431 provided with the second suction opening 331b is disposed at a position where the center between the adjacent suction-side groove portions 431 respectively provided with the second suction openings 331b coincides with the 90-degree direction on the first substrate W1.

The supply opening 340 is plural in number (e.g., eight), and these supply openings 340 are arranged in the bottom surface 170a of the main body 170. The plurality of supply openings 340 are arranged along the circumferential direction at positions radially inward with respect to the outer attraction sections 301, near the outer periphery of the main body 170. By way of example, the supply openings 340 are arranged along the same circumferential direction as the circumferential direction of the circle on which the suction openings 331 are arranged.

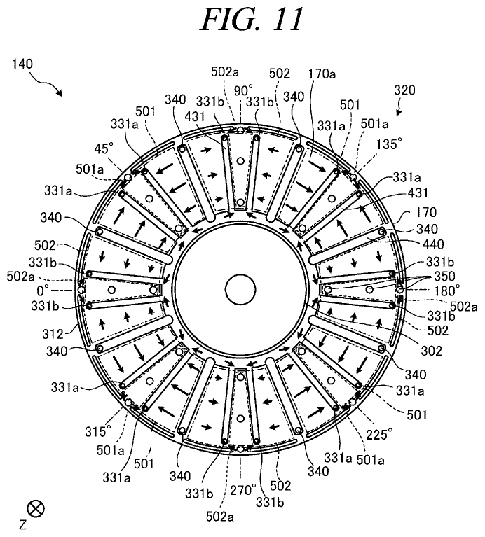

Specifically, the plurality of supply openings 340 are arranged at an interval of 45 degrees, and each supply opening 340 is located between one pair of first suction openings 331a and one pair of second suction openings 331b. To elaborate, the supply openings 340a are arranged between the 45-degree direction and the 90-degree direction on the first substrate W1. In other words, the plurality of supply openings 340 are disposed between a first negative pressure region 501 including one pair of first suction openings 331a and a second negative pressure region 502 including one pair of second suction openings 331b (both of which will be described later; see FIG. 11).

The supply opening 340 is configured to penetrate, for example, the main body 170 to communicate with the atmospheric pressure space (external space). Therefore, when a suction operation is started in the aforementioned suction opening 331, a gas from the atmospheric pressure space is introduced (supplied) through the supply opening 340.

The supply-side groove portion 440 is provided with the supply opening 340. Therefore, like the supply openings 340, there are a plurality of (e.g., eight) supply-side groove portions 440. Specifically, the supply-side groove portions 440 are formed on the bottom surface 170a of the main body 170. The supply-side groove portions 440 are formed at positions radially inward with respect to the outer attraction sections 301 and radially outward with respect to the inner attraction section 302. The supply-side groove portion 440 is a long groove in a plan view, and is formed so that the lengthwise direction thereof extends in the radial direction on the bottom surface 170a of the main body 170. In other words, the supply-side groove portion 440 is formed radially from the center of the bottom surface 170a of the main body 170 toward the outer periphery thereof.

The supply opening 340 is provided at a recessed portion 440a, which is an outer portion of the supply-side groove portion 440 in the radial direction. In this way, since the supply opening 340 is formed at the supply-side groove portion 440, it is not in direct contact with the first substrate W1. Although not shown, the supply-side groove portion 440 is formed so that its depth is constant or approximately constant as it goes from a radially outer side to a radially inner side.

The arrangement position of the supply-side groove portion 440 will be described in detail. As illustrated in FIG. 9, the supply-side groove portion 440 is disposed between the suction-side groove portion 431 in which the first suction opening 331a is provided and the suction-side groove portion 431 in which the second suction opening 331b is provided. Specifically, the supply-side groove portion 440 is disposed between the 45-degree direction and the 90-degree direction on the first substrate W1.

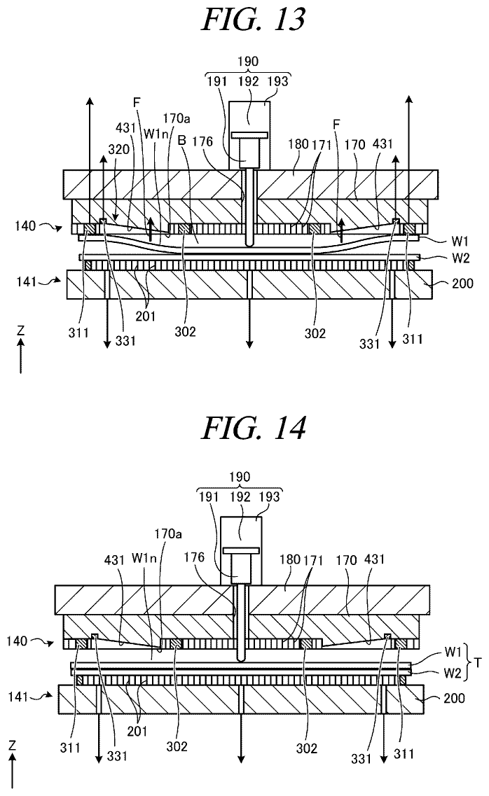

Now, formation of the negative pressure by the negative pressure formation section 320 will be explained. As described above, the negative pressure formation section 320 forms a negative pressure in a space B (see FIG. 13) between the bottom surface 170a of the main body 170 and the top surface W1nof the first substrate W1. This space B is formed as the first substrate W1 and the main body 170 are spaced apart from each other when the striker 190 presses the central portion of the first substrate W1 attracted to and held by the first holder 140 into contact with the second substrate W2.

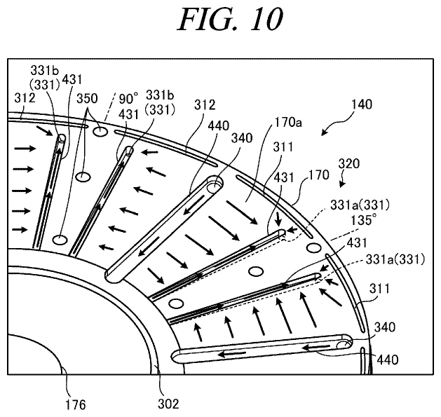

Here, the formation of the negative pressure will be explained in detail with reference to FIG. 10 and FIG. 11. FIG. 10 is a schematic perspective view that provides an enlarged view of the bottom surface 170a side of the main body 170. FIG. 11 is a schematic diagram of the first holder 140 seen from below. In addition, in FIG. 10 and FIG. 11, for the sake of ease of understanding, illustration of the first substrate W1 attracted to and held by the first holder 140 is omitted. In FIG. 10 and FIG. 11, a flow of a gas is indicated by arrows, and the length of each arrow indicates the speed of the flow (flow velocity) of the gas. Specifically, the longer the arrow, the higher the flow velocity.

As illustrated in FIG. 10 and FIG. 11, the negative pressure formation section 320 according to the present exemplary embodiment forms the negative pressure in the space B by generating the flow of the gas along the bottom surface 170a of the main body 170.

To elaborate, once the suction operation is started in the suction openings 331 as the first suction pump 174b and the second suction pump 175b are driven (see FIG. 9), a gas from the atmospheric pressure space is introduced through the supply openings 340, as shown in FIG. 10. The gas introduced from each supply opening 340 flows through the supply-side groove portion 440 and flows toward the adjacent suction-side groove portion 431 among the plurality of suction-side groove portions 431 respectively provided with the suction openings 331. That is, the gas introduced from the supply openings 340 flows out from the supply-side groove portions 440, and flows along the bottom surface 170a of the main body 170. Here, the gas flows in the circumferential direction on the bottom surface 170a of the main body 170. The gas that has flown along the bottom surface 170a of the main body 170 then flows into the suction-side groove portions 431. The gas introduced into the suction-side groove portions 431 is sucked in through the suction opening 331 to be exhausted.

In this way, the negative pressure formation section 320 generates the flow of the gas along the bottom surface 170a of the main body 170. The generation of such a flow of the gas (i.e., generation of a gas current) causes the formation of the negative pressure in the space B between the bottom surface 170a of the main body 170 and the top surface Win of the first substrate W1, so that a vertical upward force F (see FIG. 13) acts on the first substrate W1. This allows the bonding speed between the substrates to be appropriately controlled, which will be described later.

Further, in the present exemplary embodiment, the negative pressure formed in the region of the 45-degree direction, where the bonding speed is the highest, is made different from the negative pressure formed in the region of 90-degree direction, where the bonding speed is the lowest, so that the bonding region A (see FIG. 7) is expanded in substantially concentric circles.

Hereinafter, as shown in FIG. 11, when the direction from the center of the first substrate W1 toward the [0-11] crystal orientation parallel to the front surface of the first substrate W1 is defined as θ degree, the regions provided at an interval of 90 degrees with respect to the direction of 45 degrees, i.e., the regions in the 45-degree direction will be referred to as “first negative pressure regions 501.” Also, the regions provided at an interval of 90 degrees with respect to the direction of 0 degree, i.e., the regions in the 90-degree direction will be referred to as “second negative pressure regions 502.” Further, in FIG. 11, for ease of understanding, the first negative pressure regions 501 are indicated by dashed dotted lines, and the second negative pressure regions 502 are indicated by dashed double-dotted lines.

In the negative pressure formation section 320 according to the present exemplary embodiment, the negative pressure in the first negative pressure region 501 and the negative pressure in the second negative pressure region 502 are set to be different from each other. Specifically, the negative pressure formation section 320 sets the negative pressure in the first negative pressure region 501 to be higher than the negative pressure in the second negative pressure region 502.

To elaborate, the aforementioned first suction opening 331a is provided in the first negative pressure region 501. The second suction opening 331b is provided in the second negative pressure region 502. A suction force from the first suction opening 331a and a suction force from the second suction opening 331b are set to be different from each other. To be specific, the suction force from the first suction opening 331a is set to be higher than the suction force from the second suction opening 331b.

As a result, the flow velocity of the gas flowing from the supply opening 340 and the supply-side groove portion 440 to the first suction opening 331a and the suction-side groove portion 431 provided with the first suction opening 331a becomes higher than the flow velocity of the gas flowing to the second suction opening 331b and the suction-side groove portion 431 provided with the second suction opening 331b. Therefore, the negative pressure in the first negative pressure region 501, where the flow velocity of the gas is higher, becomes higher than the negative pressure in the second negative pressure region 502, where the flow velocity of the gas is lower than that in the first negative pressure region 501.

Therefore, since the negative pressure is high in the first negative pressure region 501, the force F (see FIG. 13) acting on the first substrate W1 also becomes strong, and, therefore, the bonding speed is suppressed relatively significantly in the region of the 45-degree direction where the bonding speed is the highest. On the other hand, in the second negative pressure region 502, since the negative pressure is lower than that in the first negative pressure region 501, the force F (see FIG. 13) acting on the first substrate W1 is also lower than that in the first negative pressure region 501. Therefore, in the second negative pressure region 502, the bonding speed is suppressed relatively slightly in the region of the 90-degree direction where the bonding speed is the lowest.

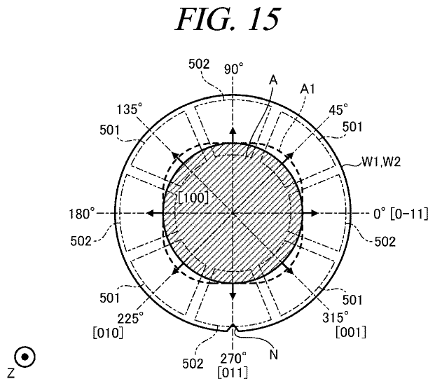

In this way, by suppressing the bonding speed in the first negative pressure region 501 and the second negative pressure region 502 using the different negative pressures, it is possible to expand the bonding region A (see FIG. 7) in substantially concentric circles (see FIG. 15 to be described later).

In the first negative pressure region 501 and the second negative pressure region 502, a negative pressure is also formed in regions 501a and 502a between the adjacent suction-side groove portions 431. Specifically, since the regions 501a and 502a are positioned between the suction-side groove portions 431 and are not adjacent to the supply-side groove portions 440, the gas is unlikely to flow in these regions 501a and 502a. However, since the gas is flowing around the regions 501a and 502a, negative-pressure walls are formed around the regions 501a and 502a, and, as a result, a negative pressure is also formed in the regions 501a and 502a surrounded by the negative-pressure walls. In this way, by arranging the multiple suction-side groove portions 431 adjacent to each other, it is possible to secure a relatively large area (here, the regions 501a and 502a) in which the negative pressure is formed.

Moreover, in the suction-side groove portion 431 in which the suction opening 331 is provided, there is a risk that the suction force decreases as it goes away from the suction opening 331. Therefore, in the suction-side groove portion 431 according to the present exemplary embodiment, the suction opening 331 is provided on the radially outer side and is formed so that its depth decreases as it goes from the radially outer side toward the radially inner side (see FIG. 6). In the present exemplary embodiment, the depth of the suction-side groove portion 431 is reduced as it goes away from the suction opening 331, so that the flow velocity can be increased at a position away from the suction opening 331 (here, near the radially inner side), and, thus, the decrease in the suction force can be suppressed. This allows the flow velocity to be uniform as much as possible in the radial direction of the bottom surface 170a of the main body 170, so that the negative pressure can be formed in the uniform manner.

Referring back to FIG. 9, the main body 170 is provided with detectors 350 configured to detect a bonding state between the first substrate W1 and the second substrate W2. As an example of the detector 350, a distance sensor configured to detect the distance from the bottom surface 170a of the main body 170 to the top surface W1n of the first substrate W1 may be used. The distance sensor may be of various types, such as an optical type, a capacitance type, a radio wave type, or an ultrasonic type.

The detectors 350 are arranged along the radial direction on the bottom surface 170a of the main body 170. When the first substrate W1 is bonded to the second substrate W2, it is bonded along the radial direction from the central portion toward the outer periphery thereof. Therefore, by arranging the detectors 350 along the radial direction, it becomes possible to monitor how far the bonding between the first substrate W1 and the second substrate W2 has progressed.

The detectors 350 according to the present exemplary embodiment are disposed between the adjacent suction-side groove portions 431. In other words, in the present exemplary embodiment, by arranging the multiple suction-side groove portions 431 adjacent to each other, a space is formed between the adjacent suction-side groove portions 431 in a plan view, and the detectors 350 are provided in this space. In this way, in the present exemplary embodiment, by arranging the multiple suction-side groove portions 431 adjacent to each other, the space in which the detectors 350 are provided can be easily secured.

Further, although the above description has been provided for the example where the detector 350 is the distance sensor, the exemplary embodiment is not limited thereto, and any of various other types of sensors may be adopted as long as they can detect the bonding state between the first substrate W1 and the second substrate W2.

Referring back to FIG. 6, the second holder 141 will be explained. The second holder 141 has a main body 200 having a diameter equal to or larger than that of the second substrate W2. Here, the second holder 141 is illustrated as having a larger diameter than the second substrate W2. A top surface of the main body 200 faces the bottom surface (non-bonding surface W2n) of the second substrate W2.

The top surface of the main body 200 is provided with multiple pins 201 that come into contact with the bottom surface (non-bonding surface Wn2) of the second substrate W2. The multiple pins 201 have a diameter of, e.g., 0.1 mm to 1 mm and a height of, e.g., several tens of μm to several hundreds of μm. The multiple pins 201 are evenly arranged at an interval of, e.g., 2 mm.

In addition, a lower rib 202 is provided in an annular shape on the top surface of the main body 200, positioned outside the multiple pins 201. The lower rib 202 is formed in the annular shape and supports the outer periphery of the second substrate W2 along the entire circumference thereof.

The main body 200 also has a plurality of (three in the present exemplary embodiment) lower suction openings 203. The plurality of lower suction openings 203 are provided in an attraction region surrounded by the lower rib 202. The plurality of lower suction openings 203 are connected to a non-illustrated suction device such as an air pump via a non-illustrated suction line.

The second holder 141 decompresses the attraction region surrounded by the lower rib 202 by evacuating the attraction region through the plurality of lower suction openings 203. As a result, the second substrate W2 placed on the attraction region is attracted to and held by the second holder 141.

Since the lower rib 202 supports the outer periphery of the bottom surface of the second substrate W2 along the entire circumference thereof, the second substrate W2 is appropriately evacuated up to its outer periphery. This allows the entire surface of the second substrate W2 to be attracted and held. Furthermore, since the bottom surface of the second substrate W2 is supported by the multiple pins 201, the second substrate W2 is easily separated from the second holder 141 when the evacuation of the second substrate W2 is released.

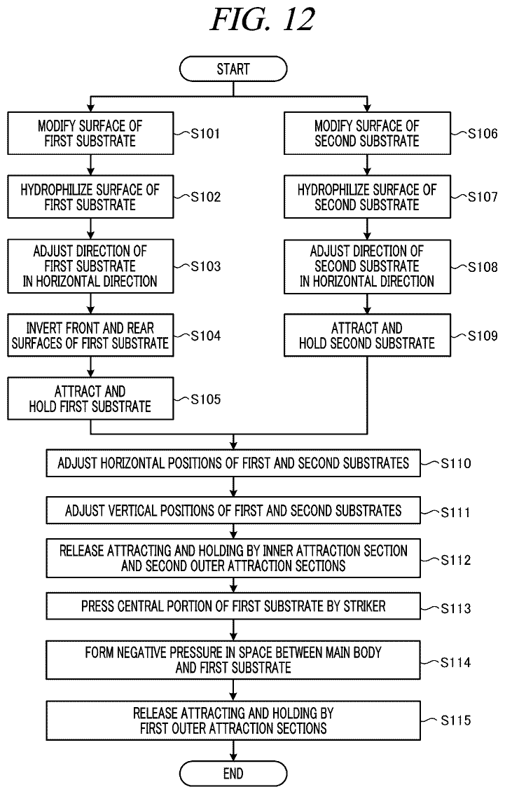

Now, a specific operation of the bonding system 1 according to the exemplary embodiment will be described with reference to FIG. 12 to FIG. 14. FIG. 12 is a flowchart showing some of the processes performed by the bonding system 1 according to the exemplary embodiment. FIG. 13 and FIG. 14 are explanatory diagrams illustrating operations in a bonding processing. The various processes shown in FIG. 12 are performed under the control of the control device 70.

First, the cassette C1 accommodating the plurality of first substrates W1, the cassette C2 accommodating the plurality of second substrates W2, and the empty cassette C3 are placed on the preset placement plates 11 of the carry-in/out station 2. Thereafter, the first substrate W1 is taken out from the cassette C1 by the transfer device 22 and transferred to the transition device 50 of the third processing block G3 of the processing station 3.

Then, the first substrate W1 is transferred by the transfer device 61 to the surface modifying apparatus 30 of the first processing block G1. In the surface modifying apparatus 30, the oxygen gas, which is the processing gas, is excited into plasma under a preset decompressed atmosphere to be ionized. These oxygen ions are radiated to the bonding surface W1j of the first substrate W1, so that the bonding surface W1j is plasma-processed. As a result, the bonding surface W1j of the first substrate W1 is modified (process S101).

Then, the first substrate W1 is transferred by the transfer device 61 to the surface hydrophilizing apparatus 40 of the second processing block G2. In the surface hydrophilizing apparatus 40, the pure water is supplied onto the first substrate W1 while rotating the first substrate W1 held by the spin chuck. The supplied pure water is diffused on the bonding surface W1j of the first substrate W1, and hydroxyl groups (silanol groups) adhere to the bonding surface W1j of the first substrate W1 modified in the surface modifying apparatus 30, thereby hydrophilizing the bonding surface W1j. In addition, the bonding surface W1j of the first substrate W1 is also cleaned by the pure water (process S102).

Next, the first substrate W1 is transferred by the transfer device 61 to the bonding apparatus 41 of the second processing block G2. The first substrate W1 carried into the bonding apparatus 41 is transferred by the substrate transfer mechanism 111 to the position adjusting mechanism 120 via the transition device 110. The position adjusting mechanism 120 then adjusts the direction of the first substrate W1 in the horizontal direction (process S103).

Thereafter, the first substrate W1 is transferred from the position adjusting mechanism 120 to the holding arm 131 of the inverting mechanism 130. Subsequently, in the transfer region T1, the holding arm 131 is inverted to turn the front and rear surfaces of the first substrate W1 upside down (process S104). That is, the bonding surface W1j of the first substrate W1 is turned to face downwards.

Afterwards, the holding arm 131 of the inverting mechanism 130 is rotated and moved to below the first holder 140. Then, the first substrate W1 is handed over from the inverting mechanism 130 to the first holder 140. Here, the non-bonding surface W1n of the first substrate W1 is attracted to and held by the first holder 140 with the notch N oriented toward a predetermined direction, i.e., the direction in which the second outer attraction section 312 is provided (process S105).

In the process S105, the first holder 140 attracts and holds the first substrate W1, using all of the outer attraction sections 301 and the inner attraction section 302.

While the above-described processes S101 to S105 are being performed on the first substrate W1, the second substrate W2 is also processed. First, the second substrate W2 is taken out of the cassette C2 by the transfer device 22 and transferred to the transition device 50 of the processing station 3.

Next, the second substrate W2 is transferred by the transfer device 61 to the surface modifying apparatus 30, where the bonding surface W2j of the second substrate W2 is modified (process S106). The modification of the bonding surface W2j of the second substrate W2 in the process S106 is the same as in the process S101 described above.

Thereafter, the second substrate W2 is transferred by the transfer device 61 to the surface hydrophilizing apparatus 40, where the bonding surface W2j of the second substrate W2 is hydrophilized and also cleaned (process S107). The hydrophilization and cleaning of the bonding surface W2j of the second substrate W2 in the process S107 is the same as in the process S102 described above.

Afterwards, the second substrate W2 is transferred to the bonding apparatus 41 by the transfer device 61. The second substrate W2 carried into the bonding apparatus 41 is transferred to the position adjusting mechanism 120 by the substrate transfer mechanism 111 via the transition device 110. The direction of the second substrate W2 is then adjusted in the horizontal direction by the position adjusting mechanism 120 (process S108).

Then, the second substrate W2 is transferred to the second holder 141 by the substrate transfer mechanism 111, and is attracted to and held by the second holder 141 (process S109). Here, the non-bonding surface W2n of the second substrate W2 is attracted to and held by the second holder 141 with the notch N oriented toward a preset direction, specifically, the same direction as the notch N of the first substrate W1 is oriented.

Next, the horizontal positions of the first substrate W1 held by the first holder 140 and the second substrate W2 held by the second holder 141 are adjusted (process S110).

Subsequently, the vertical positions of the first substrate W1 held by the first holder 140 and the second substrate W2 held by the second holder 141 are adjusted (process S111). Specifically, the first mover 160 moves the second holder 141 vertically upwards to bring the second substrate W2 close to the first substrate W1. As a result, the distance between the bonding surface W2j of the second substrate W2 and the bonding surface W1j of the first substrate W1 is adjusted to a predetermined distance, for example, 50 μm to 200 μm.

Next, after releasing the attracting and holding of the first substrate W1 by the inner attraction section 302 and the second outer attraction sections 312 (process S112), the pressing pin 191 of the striker 190 is lowered to press down the central portion of the first substrate W1 (process S113). By attracting and holding the central portion of the first substrate W1 by the inner attraction section 302 until immediately before the striker 190 presses down the first substrate W1, it is possible to suppress self-weight bending (for example, about 1 μm) of the central portion of the first substrate W1.

Once the central portion of the first substrate W1 comes into contact with the central portion of the second substrate W2 and the central portion of the first substrate W1 and the central portion of the second substrate W2 are pressed with a predetermined force by the striker 190, bonding begins between the pressed central portions of the first and second substrates W1 and W2. That is, since the bonding surface W1j of the first substrate W1 and the bonding surface W2j of the second substrate W2 have been modified in the processes S101 and S106, respectively, a van der Waals force (intermolecular force) is first generated between the bonding surfaces W1j and W2j, so that the bonding surfaces W1j and W2j are bonded to each other. Furthermore, since the bonding surface W1j of the first substrate W1 and the bonding surface W2j of the second substrate W2 have been hydrophilized in the processes S102 and S107, respectively, hydrophilic groups between the bonding surfaces W1j and W2j form hydrogen bonds, so that the bonding surfaces W1j and W2j are firmly bonded to each other. In this way, the bonding region A (see FIG. 7) is formed.

Thereafter, the bonding wave occurs between the first substrate W1 and the second substrate W2, whereby the bonding region A expands from the central portions toward the outer peripheries of the first and second substrates W1 and W2 (see FIG. 8).

In addition, when the bottom surface 170a of the main body 170 and the top surface W1n of the first substrate W1 are spaced apart by the pressing of the striker 190, the negative pressure is formed in the space B between the bottom surface 170a of the main body 170 and the top surface W1n of the first substrate W1 that are spaced apart from each other (process S114). This allows the bonding speed between the substrates to be appropriately suppressed, thereby improving the bonding accuracy between the substrates.

Specifically, the control device 70 drives the first suction pump 174b and the second suction pump 175b to start the suction operations in the suction openings 331 (more precisely, the first suction openings 331a and the second suction openings 331b). This causes the gas introduced from the supply openings 340 or the like to flow on the bottom surface 170a of the main body 170. The generation of such a flow of the gas creates the negative pressure in the space B between the bottom surface 170a of the main body 170 and the top surface W1n of the first substrate W1, so that the vertical upward force F acts on the first substrate W1.

In the present exemplary embodiment, the negative pressure in the first negative pressure region 501, which is the region in the 45-degree direction where the bonding region A expands fastest, is set to be higher than the negative pressure in the second negative pressure region 502, which is the region in the 90-degree direction where the bonding region A expands most slowly.

Here, the expansion of the bonding region A in the case where the negative pressure as described above is formed will be explained with reference to FIG. 15. FIG. 15 is a schematic diagram showing an example of the expansion of the bonding region A in the bonding apparatus 41 according to the present exemplary embodiment. In FIG. 15, for ease of understanding, the positions of the first negative pressure regions 501 and the second negative pressure regions 502 are shown. Further, for ease of understanding, FIG. 15 also provides the expansion of the bonding region in the case where the negative pressure is not formed, that is, the expansion of the bonding region shown in FIG. 8, which is indicated by a dashed line and is assigned a notation A1.

As illustrated in FIG. 15, in the first negative pressure region 501, since the negative pressure is high, the force F (see FIG. 13) acting on the first substrate W1 is also high. Therefore, in the first negative pressure region 501 in the 45-degree direction where the bonding speed is the highest, the bonding speed is suppressed to a relatively large extent. In the second negative pressure region 502, since the negative pressure is lower than that in the first negative pressure region 501, the force F acting on the first substrate W1 is also lower than that in the first negative pressure region 501. As a result, in the second negative pressure region 502 in the 90-degree direction where the bonding speed is the lowest, the bonding speed is suppressed to a relatively small extent. This makes it possible to expand the bonding region A in substantially concentric circles, as compared to the bonding region A1 in the case where no negative pressure is formed. Therefore, the bonding accuracy between the substrates may be improved.

The suction operation in the suction openings 331 shown in FIG. 13, etc., is performed from before the pressing of the striker 190 is started until the bonding of the substrates is completed, but is not limited thereto. That is, the suction operation in the suction openings 331 may be performed after the pressing of the striker 190 is begun. Also, the suction operation in the suction openings 331 may be finished before the bonding of the substrates is completed. That is, the timing for the start and the end of the suction operation in the suction openings 331 may be set as required.

In addition, in the bonding apparatus 41 according to the present exemplary embodiment, the first substrate W1 is attracted and held by using, among the plurality of outer attraction sections 301 arranged according to the anisotropy of the first substrate W1, only the first outer attraction sections 311 located in the 45-degree direction where the bonding region A expands fastest. In other words, the first substrate W1 is not attracted and held in the 90-degree direction where the bonding region A expands most slowly.

This makes it possible to reduce the unevenness in distributions of stress and strain applied to the first substrate W1, as compared to the case where the entire outer circumference of the first substrate W1 is attracted and held. As a result, the unevenness in the bonding wave is reduced, so that the bonding region A expands in substantially concentric circles. Thus, in the bonding apparatus 41 according to the present exemplary embodiment, the deformation (distortion) of the combined substrate T caused by the anisotropy can be reduced, so that the bonding accuracy between the substrates can be bettered.

Thereafter, the attracting and holding of the first substrate W1 by the first outer attraction section 311 is released (process S115). This causes the outer peripheral portion of the first substrate W1 in the 45-degree direction once attracted to and held by the first outer attraction section 311 to fall down. As a result, as illustrated in FIG. 14, the entire bonding surface W1j of the first substrate W1 and the entire bonding surface W2j of the second substrate W2 come into contact with each other, forming the combined substrate T.

Subsequently, the pressing pin 191 is raised up to the first holder 140, and the attracting and holding of the second substrate W2 by the second holder 141 is released. Afterwards, the combined substrate T is transferred to the transition device 51 by the transfer device 61, and then transferred to the cassette C3 by the transfer device 22 of the carry-in/out station 2. In this way, the series of processes of the bonding processing is completed.

As described above, the bonding apparatus 41 according to the present exemplary embodiment includes the first holder 140, the second holder 141, and the striker 190. The first holder 140 attracts and holds the first substrate W1 from above. The second holder 141 is disposed below the first holder 140 and serves to attract and hold the second substrate W2 from below. The striker 190 presses the central portion of the first substrate W1 to bring it into contact with the second substrate W2. The first holder 140 includes the main body 170 and the negative pressure formation section 320. The main body 170 has the bottom surface 170a facing the first substrate W1. The negative pressure formation section 320 forms the negative pressure in the space B between the bottom surface 170a of the main body 170 and the top surface W1n of the first substrate W1, which are spaced apart from each other by the pressing of the striker 190. As a result, the bonding accuracy between the substrates can be improved.

The negative pressure formation section 320 forms the negative pressure in the space B by generating the flow of the gas along the bottom surface 170a of the main body 170. This allows the negative pressure to be reliably formed in the space B.

Also, the negative pressure formation section 320 forms the negative pressure in the space B by generating the flow of the gas along the circumferential direction on the bottom surface 170a of the main body 170. This allows the negative pressure to be formed in a relatively wide area, conforming to the circumference of the bottom surface 170a of the main body 170.

Further, the negative pressure formation section 320 includes the suction openings 331, and the suction-side groove portions 431 respectively provided with the suction openings 331 and extending in the radial direction on the bottom surface 170a of the main body 170. With this configuration, it is possible to reliably form the flow of the gas along the bottom surface 170a of the main body 170.

The suction opening 331 is provided at the outer portion of the suction-side groove portion 431 in the radial direction. The suction-side groove portion 431 is formed so that its depth decreases as it goes from the radially outer side toward the radially inner side. In this way, since the depth of the suction-side groove portion 431 decreases as it goes away from the suction opening 331, the flow velocity at the position away from the suction opening 331 (here, near the radially inner side) can be increased, and, thus, the decrease in the suction force can be suppressed. This allows the gas to flow with the uniform flow velocity in the radial direction of the bottom surface 170a of the main body 170, thereby making it possible to form the negative pressure in the uniform manner.

In addition, the suction-side groove portion 431 is plural in number. The plurality of suction-side groove portions 431 are arranged adjacent to each other on the bottom surface 170a of the main body 170. With this configuration, the region (e.g., the regions 501a and 502a) where the negative pressure is formed can be made relatively large.

Further, the detectors 350 configured to detect the bonding state between the first substrate W1 and the second substrate W2 are provided between the adjacent suction-side groove portions 431. In this way, by arranging the plurality of suction-side groove portions 431 adjacent to each other, it is possible to easily secure the space for the detectors 350.

Furthermore, the negative pressure formation section 320 is provided with the supply openings 340, and the supply-side groove portions 440 respectively provided with the supply openings 340 and extending in the radial direction on the bottom surface 170a of the main body 170. With this configuration, the flow of the gas along the bottom surface 170a of the main body 170 can be reliably formed by using the gas introduced from the supply openings 340.

The negative pressure formation section 320 forms the negative pressure in the space B between the top surface W1n of the first substrate W1 and the four first negative pressure regions 501 arranged at an interval of 90 degrees on the bottom surface 170a of the main body 170, and forms the negative pressure in the space B between the top surface W1n of the first substrate W1 and the four second negative pressure regions 502 arranged on the bottom surface 170a of the main body 170, shifted from the four first negative pressure regions 501 by 45 degrees in the circumferential direction. Also, the negative pressure formation section 320 sets the negative pressure in the first negative pressure region 501 to be different from the negative pressure in the second negative pressure region 502. This makes it possible to expand the bonding region A (see FIG. 7 and FIG. 15) in the substantially concentric circles, thereby improving the bonding accuracy between the substrates.

The first substrate W1 is a single-crystal silicon wafer with the [100] crystal orientation on its front surface. The four first negative pressure regions 501 are arranged at the interval of 90 degrees with respect to the 45-degree direction, when the direction from the center of the first substrate W1 toward the [0-11] crystal orientation parallel to the front surface of the first substrate W1 is defined as 0 degree. This allows the bonding speed to be suppressed to a relatively large extent in the region of 45-degree direction (first negative pressure region 501) where the bonding speed is the highest.

Additionally, the present disclosure may also adopt the following configurations.
(1)

A bonding apparatus, including:
a first holder configured to hold a first substrate from above;
a second holder disposed below the first holder, and configured to attract and hold a second substrate from below; and
a striker configured to press a central portion of the first substrate into contact with the second substrate,
wherein the first holder includes:
a main body having a bottom surface facing the first substrate; and
a negative pressure formation section configured to form a negative pressure in a space between the bottom surface of the main body and a top surface of the first substrate that are spaced apart from each other as a result of being pressed by the striker.
(2)

The bonding apparatus of (1),
wherein the negative pressure formation section forms the negative pressure in the space by generating a flow of a gas along the bottom surface of the main body.
(3)

The bonding apparatus of (1) or (2),
wherein the negative pressure formation section forms the negative pressure in the space by generating the flow of the gas along a circumferential direction on the bottom surface of the main body.
(4)

The bonding apparatus of any one of (1) to (3),
wherein the negative pressure formation section includes:
a suction opening; and
a suction-side groove portion provided with the suction opening, and extending in a radial direction on the bottom surface of the main body.
(5)

The bonding apparatus of (4),
wherein the suction opening is provided at an outer portion of the suction-side groove portion in the radial direction, and
the suction-side groove portion is formed such that a depth thereof decreases as it goes from a radially outer side toward a radially inner side.
(6)

The bonding apparatus of (4) or (5),
wherein the suction-side groove portion includes multiple suction-side groove portions, and
the multiple suction-side groove portions are arranged adjacent to each other on the bottom surface of the main body.
(7)

The bonding apparatus of (6),
wherein a detector configured to detect a bonding state between the first substrate and the second substrate is provided between the adjacent suction-side groove portions.
(8)

The bonding apparatus of any one of (1) to (7),
wherein the negative pressure formation section includes:
a supply opening; and
a supply-side groove portion provided with the supply opening, and extending in a radial direction on the bottom surface of the main body.
(9)

The bonding apparatus of any one of (1) to (8),
wherein the negative pressure formation section forms the negative pressure in the space between the top surface of the first substrate and four first negative pressure regions arranged at an interval of 90 degrees on the bottom surface of the main body,
the negative pressure formation section also forms the negative pressure in the space between the top surface of the first substrate and four second negative pressure regions respectively arranged to be shifted by 45 degrees from the four first negative pressure regions in a circumferential direction on the bottom surface of the main body, and
the negative pressure in the first negative pressure regions and the negative pressure in the second negative pressure regions are set to be different from each other.
(10)

The bonding apparatus of (9),
wherein the first substrate is a single-crystal silicon wafer with a [100] crystal orientation on a surface thereof, and
the four first negative pressure regions are arranged at an interval of 90 degrees with respect to a direction of 45 degrees when a direction from the central portion of the first substrate toward a [0-11] crystal orientation, which is parallel to the surface of the first substrate, is defined as 0 degree.
(11)

A bonding system, including:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus includes:
a first holder configured to hold the first substrate from above;
a second holder disposed below the first holder, and configured to attract and hold the second substrate from below; and
a striker configured to press a central portion of the first substrate into contact with the second substrate, and
the first holder includes:
a main body having a bottom surface facing the first substrate; and
a negative pressure formation section configured to form a negative pressure in a space between the bottom surface of the main body and a top surface of the first substrate that are separated from each other as a result of being pressed by the striker.
(12)

A bonding method, including:
attracting and holding a first substrate from above with a first holder, the first holder including a main body having a bottom surface facing the first substrate, and a negative pressure formation section;
attracting and holding a second substrate from below with a second holder disposed below the first holder;
pressing a central portion of the first substrate into contact with the second substrate by a striker; and
forming, with the negative pressure formation section, a negative pressure in a space between the bottom surface of the main body and a top surface of the first substrate that are spaced apart from each other as a result of being pressed by the striker.

It should be noted that the above-described exemplary embodiments are illustrative in all aspects and are not anyway limiting. In fact, the above-described exemplary embodiment may be embodied in various forms. The above-described exemplary embodiment may be omitted, replaced and modified in various ways without departing from the scope and the spirit of claims.

### EXPLANATION OF CODES

W1: First substrate
W2: Second substrate
1: Bonding system
41: Bonding apparatus
140: First holder
141: Second holder
170: Main body
190: Striker
320: Negative pressure formation section

1. A bonding apparatus, comprising:
a first holder configured to hold a first substrate from above the first substrate;
a second holder disposed below the first holder, and configured to attract and hold a second substrate from below the second substrate; and
a striker configured to press a central portion of the first substrate into contact with the second substrate,
wherein the first holder comprises:
a main body having a bottom surface facing the first substrate; and
a negative pressure formation section configured to form a negative pressure in a space between the bottom surface of the main body and a top surface of the first substrate that are spaced apart from each other as a result of being pressed by the striker.

2. The bonding apparatus of claim 1,
wherein the negative pressure formation section forms the negative pressure in the space by generating a flow of a gas along the bottom surface of the main body.

3. The bonding apparatus of claim 2,
wherein the negative pressure formation section forms the negative pressure in the space by generating the flow of the gas along a circumferential direction on the bottom surface of the main body.

4. The bonding apparatus of claim 1,
wherein the negative pressure formation section comprises:
a suction opening; and
a suction-side groove portion provided with the suction opening, the suction-side groove portion extending in a radial direction on the bottom surface of the main body.

5. The bonding apparatus of claim 4,
wherein the suction opening is provided at an outer portion of the suction-side groove portion in the radial direction, and
a depth of the suction-side groove portion decreases from a radially outer side of the suction-side groove portion toward a radially inner side of the suction-side groove portion.

6. The bonding apparatus of claim 4,
wherein the suction-side groove portion is a first suction-side groove portion among a plurality of suction-side groove portions, and
the plurality of suction-side groove portions are arranged adjacent to each other on the bottom surface of the main body.

7. The bonding apparatus of claim 6, further comprising
a detector configured to detect a bonding state between the first substrate and the second substrate, the detector being provided between two adjacent of the plurality of suction-side groove portions.

8. The bonding apparatus of claim 1,
wherein the negative pressure formation section comprises:
a supply opening; and
a supply-side groove portion provided with the supply opening, the supply-side groove portion extending in a radial direction on the bottom surface of the main body.

9. The bonding apparatus of claim 1,
wherein the negative pressure formation section forms the negative pressure in the space between the top surface of the first substrate and four first negative pressure regions arranged at an interval of 90 degrees on the bottom surface of the main body,
the negative pressure formation section also forms the negative pressure in the space between the top surface of the first substrate and four second negative pressure regions respectively arranged to be shifted by 45 degrees from the four first negative pressure regions in a circumferential direction on the bottom surface of the main body, and
the negative pressure in the first negative pressure regions and the negative pressure in the second negative pressure regions are set to be different from each other.

10. The bonding apparatus of claim 9,
wherein the first substrate is a single-crystal silicon wafer with a <100> crystal orientation on a surface thereof, and
the four first negative pressure regions are arranged at an interval of 90 degrees with respect to a direction of 45 degrees when a direction from the central portion of the first substrate toward a <0-11> crystal orientation, which is parallel to the surface of the first substrate, is defined as 0 degree.

11. A bonding system, comprising:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus comprises:
a first holder configured to hold the first substrate from above the first holder;
a second holder disposed below the first holder, and configured to attract and hold the second substrate from below the second holder; and
a striker configured to press a central portion of the first substrate into contact with the second substrate, and
the first holder comprises:
a main body having a bottom surface facing the first substrate; and
a negative pressure formation section configured to form a negative pressure in a space between the bottom surface of the main body and a top surface of the first substrate that are separated from each other as a result of being pressed by the striker.

12. A bonding method, comprising:
attracting and holding a first substrate from above with a first holder, the first holder comprising:
a main body having a bottom surface facing the first substrate; and
a negative pressure formation section;
attracting and holding a second substrate from below with a second holder disposed below the first holder;
pressing a central portion of the first substrate into contact with the second substrate by a striker; and
forming, with the negative pressure formation section, a negative pressure in a space between the bottom surface of the main body and a top surface of the first substrate that are spaced apart from each other as a result of being pressed by the striker.

13. The bonding system of claim 11,
wherein the negative pressure formation section forms the negative pressure in the space by generating a flow of a gas along the bottom surface of the main body.

14. The bonding system of claim 13,
wherein the negative pressure formation section forms the negative pressure in the space by generating the flow of the gas along a circumferential direction on the bottom surface of the main body.

15. The bonding system of claim 11,
wherein the negative pressure formation section comprises:
a suction opening; and
a suction-side groove portion provided with the suction opening, the suction-side groove portion extending in a radial direction on the bottom surface of the main body.

16. The bonding system of claim 15,
wherein the suction opening is provided at an outer portion of the suction-side groove portion in the radial direction, and
a depth of the suction-side groove portion decreases from a radially outer side of the suction-side groove portion toward a radially inner side of the suction-side groove portion.

17. The bonding system of claim 15,
wherein the suction-side groove portion is a first suction-side groove portion among a plurality of_suction-side groove portions, and
the plurality of suction-side groove portions are arranged adjacent to each other on the bottom surface of the main body.

18. The bonding system of claim 17, further comprising a detector configured to detect a bonding state between the first substrate and the second substrate, the detector being provided between two adjacent suction-side groove portions.

19. The bonding system of claim 11,
wherein the negative pressure formation section forms the negative pressure in the space between the top surface of the first substrate and four first negative pressure regions arranged at an interval of 90 degrees on the bottom surface of the main body,
the negative pressure formation section also forms the negative pressure in the space between the top surface of the first substrate and four second negative pressure regions respectively arranged to be shifted by 45 degrees from the four first negative pressure regions in a circumferential direction on the bottom surface of the main body, and
the negative pressure in the first negative pressure regions and the negative pressure in the second negative pressure regions are set to be different from each other.

20. The bonding system of claim 19,
wherein the first substrate is a single-crystal silicon wafer with a <100> crystal orientation on a surface thereof, and
the four first negative pressure regions are arranged at an interval of 90 degrees with respect to a direction of 45 degrees when a direction from the central portion of the first substrate toward a <0-11> crystal orientation, which is parallel to the surface of the first substrate, is defined as 0 degree.
